(19) United States
(12) Patent Application Publication
(10) Pub. No.: US 2010/0052122 A1
(43) Pub. Date: Mar. 4, 2010

(54) WIRE BODNING PACKAGE STRUCTURE

(75) Inventor: Bernd Karl Appelt, Gulf Breeze, FL (US)

Correspondence Address: J C PATENTS, 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/199,141

(22) Filed: Aug. 27, 2008

(51) Int. Cl. H01L 23/495

(52) U.S. Cl. 257/676; 257/E23.04

(57) ABSTRACT

A chip package structure employing a die pad integrated with the ground/voltage pad is provided. The die pad for carrying the chip is split into at least two separate sections for accommodating the ground and the voltage. Due to the design of the die pad, the signal fingers may be extended under the chip to be connected with vias, and thermal/ground vias may be arranged under the die pad for thermal or electrical connections. Through such arrangement, all the fingers are located closer to the die, thus decrease the length of bonding wires and reducing the package dimensions.

### BACKGROUND OF THE INVENTION

1. Field of the Invention

The present invention relates to a chip package structure. More particularly, the present invention relates to wire bonding package structure.

2. Description of Related Art

Typical die bond adhesives are in liquid forms and dispensed within the area of the die foot print for fixating the chips to the die pad. As the chip is pressed into the liquid-state adhesive, the adhesive overflows to the edges of the chip and wicks up on the sides of the chip to form a fillet. The overflowed adhesive may impair or fail wire bonding in the subsequent processes by wicking out up on die bond pads or by wicking over die bond fingers and ground or voltage pads surrounding the die.

To ensure successful wire bonding, a plasma process may be required to remove the overflowed adhesive. However, additional plasma process adds to the assembly costs of the package structure. Alternatively, a solder mask dam may be designed around the die pad to alleviate the overflow issues of the adhesive. Still, such approach may increase the package size and/or the package costs.

For a conventional chip package structure, the power ring and the ground ring, generally surround the die pad, so that the chip disposed on the die pad is electrically connected to the power ring, the ground ring and other contacts through a plurality of bonding wires. However, due to the design of the power ring and the ground ring, the bonding wires span a long distance, and the package size of the chip package structure can not be reduced.

### SUMMARY OF THE INVENTION

The present invention provides a chip package structure employing a die pad integrated with the ground/voltage pad and/or thermal/ground vias. Furthermore, the chip is attached to the die pad through a film-type bond adhesive.

The present invention provides a chip package structure comprising a carrier having a die pad, a chip disposed over the die pad and electrically connected to the carrier and a bond adhesive between the carrier and the chip. The die pad includes at least two sections and different fingers are respectively connected to two individual sections for electrical functions.

According to an embodiment in the present invention, at least two individual sections of the die pad respectively accommodate the voltage or the ground. In the present invention, the die pad is split into individual sections and certain sections function as the ground/voltage pads, thus saving the space occupied by the ground/voltage ring and effectively reducing the package sizes.

According to an embodiment in the present invention, signal vias are arranged in the open area of the die pad and the signal fingers may extend under the chip to be connected with the signal vias. The signal fingers may be interdigitated with the ground/voltage fingers, which is particularly beneficial for high density package structures with tight design rules.

According to an embodiment in the present invention, thermal/ground vias may be further incorporated under the die pad for thermal or electrical connections.

### BRIEF DESCRIPTION OF THE DRAWINGS

FIG. 1 is a schematic cross-sectional view showing a chip package structure according to an embodiment of the present invention.

FIG. 2A is a schematic top view showing an example of a chip package structure according to an embodiment of the present invention.

FIG. 2B is a schematic top view showing another example of a chip package structure according to an embodiment of the present invention.

### DESCRIPTION OF EMBODIMENTS

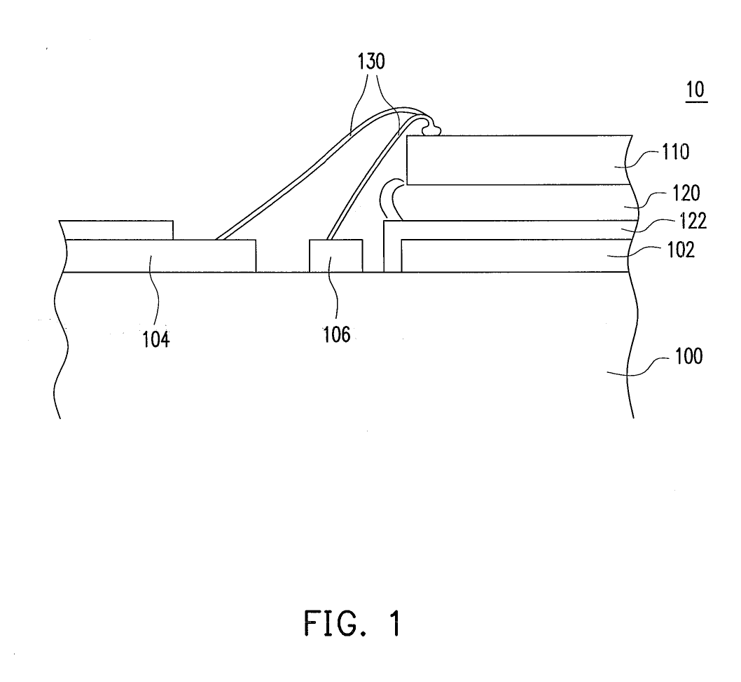

FIG. 1 is a schematic cross-sectional view showing a chip package structure according to an embodiment of the present invention. Referring to FIG. 1, a chip package structure 10 comprises a carrier 100 and at least a chip 110. The carrier 100 can be a multi-layered substrate having at least a patterned metal layer disposed on the top surface of the core. In the present embodiment, the carrier 100 comprises a die pad 102, at least a ground/voltage ring 106 and a plurality of bond fingers or traces 104 (only one is shown) for electrical contacts. The chip 110 is disposed on the die pad 102 and attached to the die pad 102 through a bond adhesive 120. The bond adhesive 120 can be, for example, any suitable film-type adhesive, such as ESP8680-WL from AI Technology Inc., EasyStack™ ATB-225-8 from Ablestik Co or Ablefilm® 5020K also from Ablestik Co, etc.. As the film type adhesive will not overflow outside the die foot print, the bond fingers or traces can be designed to be closer to the die, which may help decrease the package size. Optionally, a solder mask 122 may be further included between the bond adhesive 120 and the die pad 102. Preferably, the solder mask 122 is skipped and the bond adhesive 120 is placed directly on the die pad 102. For enhancing thermal, performance, the adhesive 120 can be added with, for example, thermally enhanced fillers. The chip 110 is electrically connected to the ground/voltage pad 104 and the bond finger/trace 106 through wires 130.

Although the ground/voltage pad 106 may be designed as a ring-shaped structure surrounding the die pad 102, the preferred design is to integrate the ground/voltage pad 106 and/or the bond fingers or traces 104 with the die pad 102.

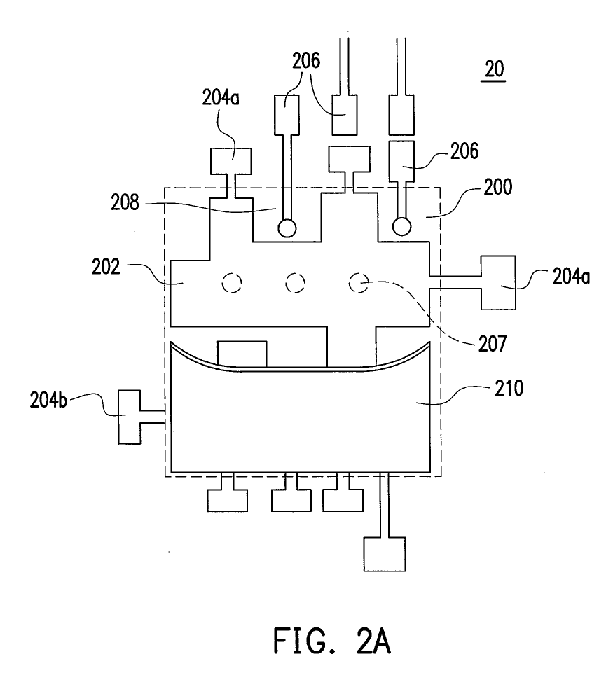

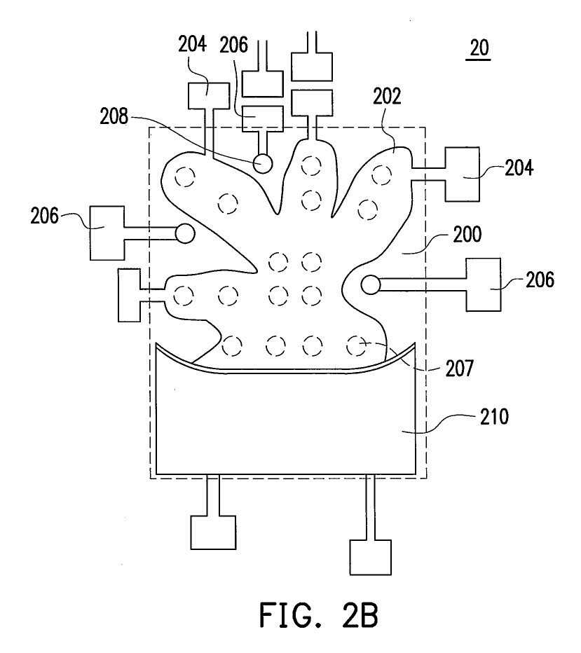

FIG. 2A is a schematic top view showing an example of a chip package structure according to an embodiment of the present invention, while FIG. 2B is a schematic top view showing another example of a chip package structure according to an embodiment of the present invention. A portion of the chip package structure 20 is removed to expose the underlying carrier 200 for the convenience of descriptions. The dotted line marks the die foot print for accommodating the chip 210. The carrier 200 comprises a die pad 202 (located within the die foot print and underlying the die 210), at least one ground finger 204a, a voltage finger 204b, and a plurality of signal fingers 206. The material of the die pad 202 may be copper formed by electroplating or laminating copper foil, for example.

Rather than the commonly used square or rectangular shape, the shape of the die pad 202 can be mostly composed of straight-lined segments (more regular shaped) (FIG. 2A) or mostly composed of curved segments (less regular shaped) (FIG. 2B), depending on the design rule or the electrical properties of the package structure. For the more regular shaped die pad, the shape of the die pad 202 may be formed from a plurality of the same of different polygons connected to one another, for example.

The design of the die pad 202 is to merge the previously outskirting ground/voltage ring into the die pad to save some space for tighter designs. Hence, the die pad 202 may be split into different sections and the respectively individual section is connected with the ground finger(s) 204a and the voltage finger(s) 204b. As shown in FIG. 2A, the upper section of the die pad 202 is connected with the protruding ground fingers 204a for accommodating the ground, while the lower section of the die pad 202 is connected with the protruding voltage fingers 204b for accommodating the voltage.

Alternatively, if the voltage is equivalent to the ground, the die pad 202 may be an integral section respectively connected with the ground/voltage finger(s) 204, as shown in FIG. 2B.

In this way, the ground/voltage pads are arranged under the chip 210 as a portion of the die pad 202 functions as the ground/voltage pad. The protruding ground/voltage fingers 204a/204b (204) allows wire bonding. As the ground/voltage pads are located under the chip 210, the ground/voltage fingers 204a/204b (204) can move closer to the die foot print. The carrier 200 may further include thermal/ground vias 207 under the die pad 202 as thermal or electrical paths. The thermal/ground vias 207 can be either plated through vias (PTH) or blind vias filled with metal or unfilled, for example.

The signal fingers 206 may extend into the open area of die pad 202 (into the die foot print) and are connected with signal vias 208 under the chip 210. As the signal finger 206 can be connected to the signal via 208 under the chip 210, the wiring/routing density of the package structure can be greatly increased. Nevertheless, for the compact packages, the signal fingers 206 may be further arranged interdigitatedly between the ground/voltage fingers 204a/204b(204) to save even more spaces. Although the die pad 202 is designed to be smaller than the chip 210, the size of the bond adhesive 120 (shown in FIG. 1) is substantially equivalent to that of the die foot print. Therefore, the chip 210 above the open area of the die pad 202 is attached directly to the carrier 200 through the bond adhesive, which enhances chip adhesion.

The arrangement of the ground/voltage fingers 204a/204b and the signal fingers 206 is flexible, depending on the design of the device or requirements of the electrical properties for the package structure. In general, the ground/voltage fingers 204a/204b and the signal fingers 206 are arranged around the die foot print, thus eliminating long distance spanning of the wires. The signal fingers 206 can be interdigitated with the ground/voltage fingers 204a/204b, for example.

The above described structure uses wire bonding single chip package structures as examples, but the scope of the present invention will not be limited by the descriptions or embodiments herein. Further advanced or high density package structures, including the stack chip package structures and the multi-chip module (MCM) packages and multi-package stacking structures, may be encompassed with the scope of this invention.

In the present invention, as the ground/voltage pads are arranged under the die and the signal fingers are partially extended into the die foot print, not only the length of bonding wire can be greatly reduced but also the package size is effectively reduced.

It will be apparent to those skilled in the art that various modifications and variations may be made to the structure of the present invention without departing l from the scope or spirit of the invention. In view of the foregoing, it is intended that the present invention cover modifications and variations of this invention provided they fall within the scope of the following claims and their equivalents.

What is claimed is:

1. A chip package structure, comprising:
a carrier, having a die pad and a plurality of first fingers, a plurality of first vias, at least a second finger and at least a third finger, wherein the die pad includes at least two sections and the second and third fingers are respectively connected to two individual sections;
a chip disposed over the carrier, and electrically connected to the carrier; and
a bond adhesive disposed over the die pad and between the die pad and the chip, wherein the chip is attached to the die pad through the bond adhesive,
wherein the first, second and third fingers are arranged around the chip, and the first vias are located by the die pad and below the chip, and the first fingers extend under the chip and are connected with the first vias.

2. The structure as claimed in claim 1, wherein the first via is a signal via and first finger is a signal finger.

3. The structure as claimed in claim 1, wherein the second finger is a ground finger and the third finger is a voltage finger, so that the section of the die pad connected to the second finger functions as a ground pad and the section of the die pad connected to the third finger functions as a voltage pad.

4. The structure as claimed in claim 1, wherein the carrier further includes a plurality of second vias under the die pad.

5. The structure as claimed in claim 4, wherein the second via is a thermal via.

6. The structure as claimed in claim 4, wherein the second via is a ground via.

7. The structure as claimed in claim 4, wherein the second via is a through-plated via.

8. The structure as claimed in claim 4, wherein the second via is a blind via.

9. The structure as claimed in claim 1, wherein the bond adhesive is a film-type adhesive.

10. The structure as claimed in claim 9, wherein the bond adhesive further includes fillers for thermal enhancement.

11. A chip package structure, comprising:
a carrier, having a die pad and a plurality of first fingers, a plurality of first vias, and a plurality of second fingers, wherein the die pad is connected to the second fingers respectively;
a chip disposed over the carrier, and electrically connected to the carrier; and
a bond adhesive disposed over the die pad and between the die pad and the chip, wherein the chip is attached to the die pad through the bond adhesive,
wherein the first and second fingers are arranged around the chip, and the first vias are located by the die pad and below the chip, and the first fingers extend under the chip and are connected with the first vias.

12. The structure as claimed in claim 11, wherein the first via is a signal via and first finger is a signal finger.

13. The structure as claimed in claim 11, wherein the second finger is a ground/voltage finger.

14. The structure as claimed in claim 11, wherein the carrier further includes a plurality of second vias under the die pad.

15. The structure as claimed in claim 14, wherein the second via is a thermal via.

16. The structure as claimed in claim 14, wherein the second via is a through-plated via.

17. The structure as claimed in claim 14, wherein the second via is a blind via.

18. The structure as claimed in claim, 11, wherein the bond adhesive is a film-type adhesive.

19. The structure as claimed in claim 18, wherein the bond adhesive further includes fillers for thermal enhancement.
